(19) United States
(12) Patent Application Publication
(10) Pub. No.: US 2010/0282443 A1
(43) Pub. Date: Nov. 11, 2010

(54) HEAT DISSIPATION DEVICE

(75) Inventors: Qing-Lei Guo, Shenzhen (CN); Shou-Li Zhu, Shenzhen (CN)

Correspondence Address: Altis Law Group, Inc.;ATTN: Steven Reiss, 288 SOUTH MAYO AVENUE, CITY OF INDUSTRY, CA, 91789, US

(73) Assignees: Fu Zhun Precision Industry (Shen Zhen) Co., Ltd., Shenzhen City (CN); Foxconn Technology Co., Ltd., Tu-Cheng (TW)

(21) Appl. No.: 11/964,893

(22) Filed: Dec. 27, 2007

(51) Int. Cl. F28F 13/06; F28D 15/04; F28F 7/00; H01L 23/467

(52) U.S. Cl. 165/104.26; 165/121; 165/185

(57) ABSTRACT

A heat dissipation device includes a fan (10) and a fin assembly (20). The fan has an air inlet and an air outlet mating with the air inlet. The fan is mounted on the fin assembly. The fin assembly has a plurality of fins (221) arranged one by one and a plurality of channels (222) formed between adjacent fins. Each fin has a main body (2210), a first flange (2211a) and a second flange (2213a). The first flange and the second flange are slantwise extended from an edge portion of the main body towards the air outlet of the fan. The first flange and the second flange are inclined with respect to the main body, and an airflow produced by the fan is guided into the channels of the fins by the first flange and the second flange of the each fin.

### BACKGROUND OF THE INVENTION

1. Field of the Invention

The present invention relates to a heat dissipation device, and particularly to a heat dissipation device having a plurality of fins to remove heat from a heat-generating component, wherein the fins have an improved structure.

2. Description of Related Art

Modern electronic devices in a computer can operate at very high speed. The faster an electronic device operates the more heat it generates. Excessive heat can make the electronic device unstable, or even cause damage to the electronic device or associated components in the computer. Therefore, heat must be removed efficiently to ensure normal operation. Typically, an extruded heat sink is mounted on a top surface of the electronic device. A fan system is commonly used to facilitate heat removal by way of convention.

A conventional heat dissipation device 120 is shown in FIG. 5. The heat dissipation device 120 includes a flat base 122, a plurality of fins 124 extending upwardly from the base 122, and a fan 126 mounted on the fins 124. During operation of the heat dissipation device 120, the fan 126 creates centrifugal outgoing airflow towards the fins 124.

Since the airflow flows out from the fan 126 in a spiral or cylindrical pattern and the fins 124 are vertical flat plates, it was difficult for the airflow produced by the fan 126 to flow into spaces between the fins 124, thus reducing the efficiency of the forced convention between the fins 124 and the airflow produced by the fan 126.

What is needed, therefore, is a heat dissipation device which can overcome the above problem.

### SUMMARY OF THE INVENTION

In accordance with an embodiment of the present invention, a heat dissipation device comprises a fan and a fin assembly. The fan has an air inlet and an air outlet mating with the air inlet. The fan is mounted on the fin assembly. The fin assembly has a plurality of fins arranged one by one and a plurality of channels formed between adjacent fins. Each fin has a main body, a first flange and a second flange. The first flange and the second flange are slantwise extended from an edge portion of the main body towards the air outlet of the fan. The first flange and the second flange are inclined with respect to the main body, and an airflow produced by the fan is guided into the channels of the fins by the first flange and the second flange of the each fin.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded view of a heat dissipation device in accordance with a preferred embodiment of the present invention;

FIG. 2 is similar to FIG. 1, but viewed from another aspect;

FIG. 3 is an assembled view of FIG. 1;

FIG. 4 is an enlarged view of a fin assembly of FIG. 1; and

FIG. 5 is an assembled view of a conventional heat dissipation device in related art.

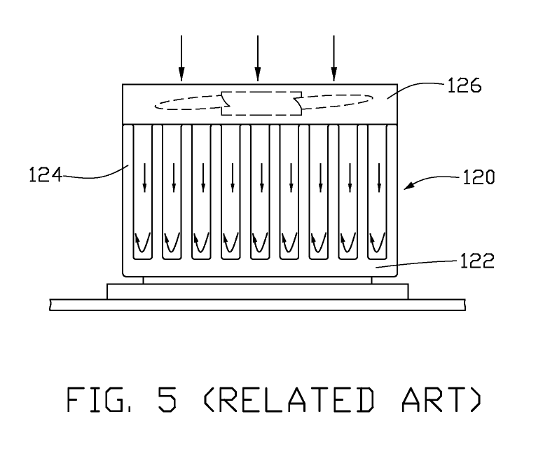

### DETAILED DESCRIPTION OF THE INVENTION

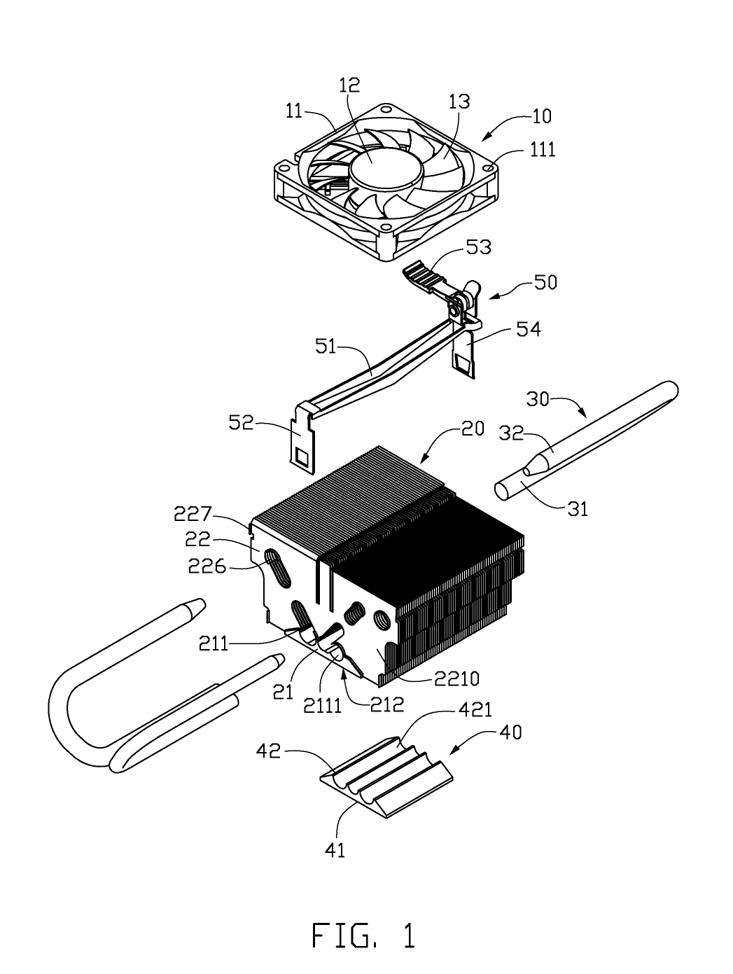

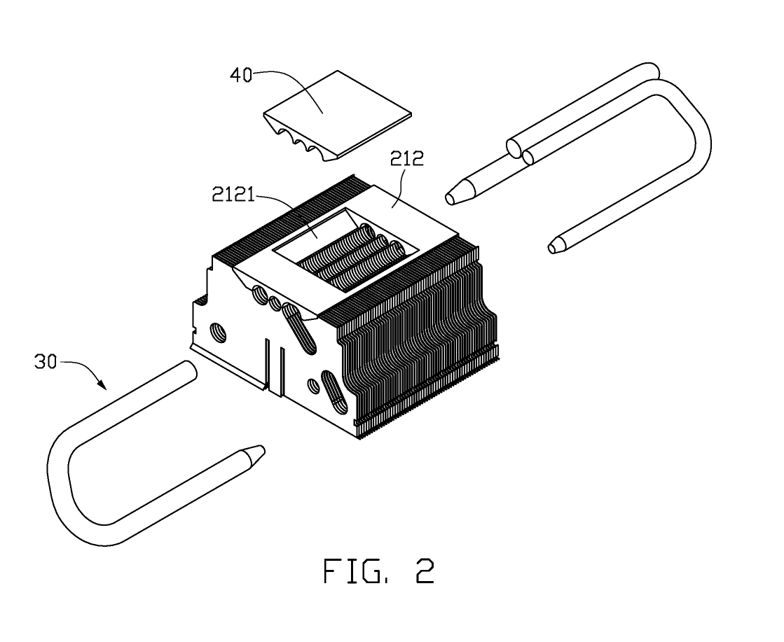

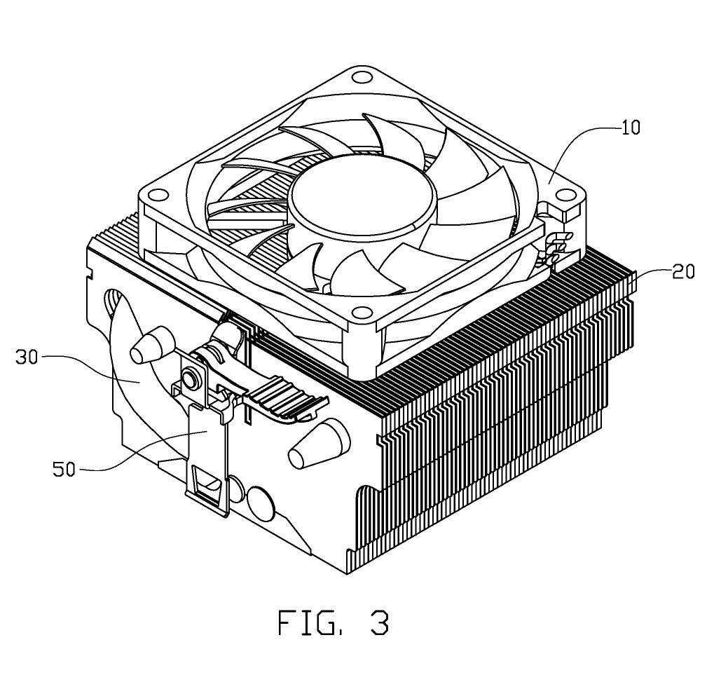

Referring to FIGS. 1-3, a heat dissipation device according to a preferred embodiment of the invention is illustrated. The heat dissipation device includes a fan 10, a heat sink 20, three heat pipes 30, a heat-absorbing block 40, and a clip 50 configured for securing the heat sink 20 on a desired component, such as a printed circuit board (not shown).

The fan 10 includes a rectangular frame 11, and an impeller 12 having a plurality of blades 13 disposed in the frame 11. A through hole 111 is defined in each corner of the frame 11 for securing the fan 10 on a top side of the heat sink 20. The fan 10 has an air inlet and an air outlet mating with the air inlet.

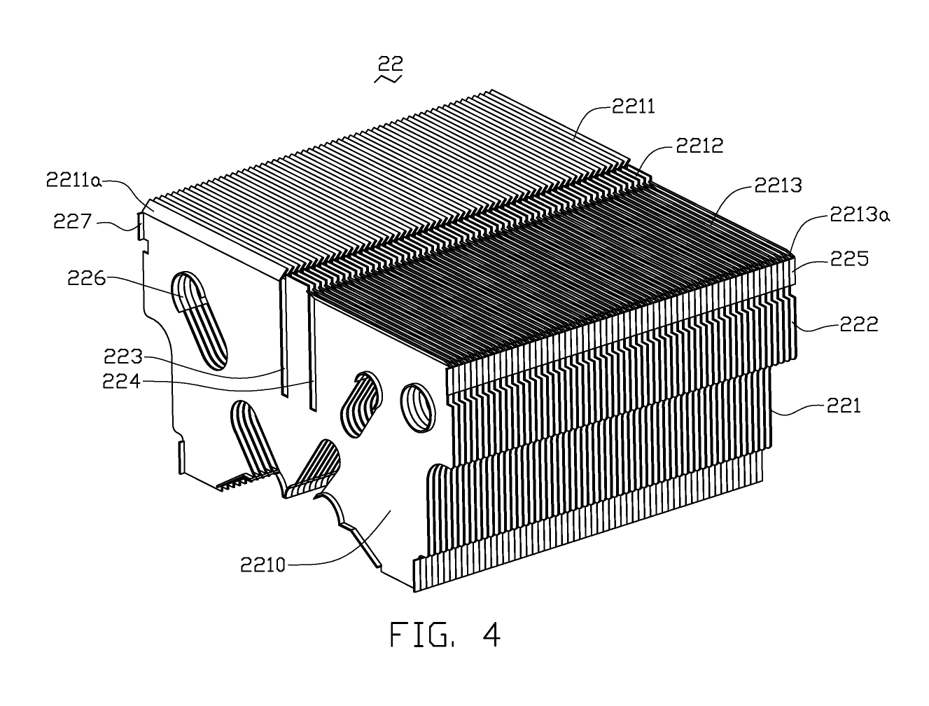

The heat sink 20 comprises a heat-transferring plate 21 mounted on the heat-absorbing block 40, and a fin assembly 22 disposed on the heat-transferring plate 21. Referring to FIG. 4, the fin assembly 22 comprises a plurality of parallel fins 221 arranged one by one, and a plurality of channels 222 is defined between adjacent fins 221. Two spaced grooves 223, 224 are defined through the fins 221 at a top portion of the fin assembly 22, and parallel extend in a direction perpendicular to the fins 221. In other words, the grooves 223, 224 extend in a direction, along which the fins 224 are arranged one by one.

The grooves 223, 224 divide each fin 221 into three portions, that is included a first fin portion 2211, a third fin portion 2212 and a second fin portion 2213 from left to right direction. The first fin portion 2211 and the second fin portion 2213 have a substantially same width, which is larger than that of the third fin portion 2212.

An upper edge portion of the first fin portion 2211 of each fin 221 is bent backwardly with respect to a main body 2210 of the each fin 221 to form a first flange 2211a. The first flange 2211a is in a direction preferably about 60 degrees relative to the vertical direction. In other words, the first flange 2211a and the main body 2210 together define an obtuse angle of preferably 120 degrees.

Similarly, an upper edge portion of the second fin portion 2213 of the each fin 221 is bent forwardly with respect to the main body 2210 of the each fin 221 to form a second flange 2213a. The second flange 2213a is in a direction about 60 degrees relative to the vertical direction. In other words, the second flange 2213a and the main body 2210 together define an obtuse angle of preferably 120 degrees.

In a word, the upper edge portions of the first fin portion 2211 and the second fin portion 2213 of each fin 221 are bent in opposite directions to form the first flange 2211a and the second flange 221 3a. When the fins 221 are arranged one by one to form the fin assembly 22, the first flanges 2211a are oriented to point the backward direction, while the second flanges 2213a are oriented to point the forward direction. The first flanges 2211a and the second flanges 2213a function as an airflow guiding structure for directing an airflow produced by the fan 10 into the channels 222 between the fins 221. Thus, an efficiency of the forced convention between the fins 221 and the airflow produced by the fan 10 is increased.

For further improved the efficiency of the forced convention, one fin 221 is connected to one adjacent fin 221 via two engaging members 227 formed at opposite sides of the one fin 221. Preferably, a top side of one of the engaging members 227 neighbores a bottom side of the first flange 2211a. A top side of the other one of the engaging members 227 neighbores a bottom side of the second flange 2213a.

When the fins 221 are connected together to form the fin assembly 22 via the engaging members 227, the engaging members 227 of the fins 221 together define two strip-like plates 225 on opposite lateral sides of the fin assembly 22. The strip-like plates 225 are located beneath and neighboring the first flanges 2211a and the second flanges 221 3a. The strip-like plates 225 together define a fan duct structure, which can prevent the airflow from exiting the fins 221 from an upper portion of the fin assembly 22 and can guide the airflow to flow downward to enhance the forced convention.

Three through holes 226 are defined through the fin assembly 22 in the upper portion of the fin assembly 22 beneath the first flanges 2211a and the second flanges 2213a. These through holes 226 are provided to receive the heat pipes 30. Each heat pipe 30 has a U-shaped profile, and comprises an evaporator 31 and a condenser 32. The condensers 32 of the heat pipes 30 are installed in the through holes 226 of the fin assembly 22. The evaporators 31 of the heat pipes 30 are in thermal engagement with the heat-absorbing block 40 and the heat-transferring plate 21.

The heat-absorbing block 40 has a flat bottom surface 41 and a top surface 42. The bottom surface 41 is in thermal contact with a heat-generating component (not shown). Three grooves 421 are defined in the top surface 42 of the heat-absorbing block 40.

The heat-transferring plate 21 is embedded into a bottom portion of the fin assembly 22. The heat-transferring plate 21 has a top surface 211 abutting against the fins 221 and a bottom surface 212. Three spaced grooves 2111 are defined in the top surface 211 of the heat-transferring plate 21. An opening 2121 is defined through the heat-transferring plate 21 from the top surface 211 to the bottom surface 212. The opening 2121 is configured for receiving the heat-absorbing block 40 therein.

When the heat-absorbing block 40 is installed in the opening 2121 of the heat-transferring plate 21, the bottom surface 41 of the heat-absorbing block 40 and the bottom surface 212 of the heat-transferring plate 21 are coplanar with each other. Meanwhile, the grooves 421 of the heat-absorbing block 40 are aligned with the corresponding grooves 2111 of the heat-transferring plate 21 to form three passages, and the evaporators 31 of the heat pipes 30 are received and retained in the passages respectively.

The clip 50 comprises a V-shaped longitudinal portion 51 at a center thereof, first and second locking arms 52, 54 extending downwardly from opposite ends of the longitudinal portion 51 and an operation portion 53 connecting with the second locking arm 54.

During assembly of the heat dissipation device, the fins 221 are first connected together to form the fin assembly 22 via the engaging members 227. Then, the heat-transferring plate 21 is embedded in the bottom portion of the fin assembly 22 and the heat-absorbing block 40 is installed in the opening 2121 of the heat-transferring plate 21 with the passages formed. Sequentially, the heat pipes 30 are installed in the heat sink 20 with the condensers 32 being inserted into the through holes 226 of the fin assembly 22 and the evaporators 31 being received in the passages respectively. The longitudinal portion 51 of the clip 50 is installed into the grooves 223, 224 of the fin assembly 22 with the operation portion 53 located at a rear side of the fin assembly 22. Finally, the fan 10 is mounted on the fin assembly 22 via fasteners (not shown) extending through the through holes 111 of the fan 10 to engage with the fin assembly 22. Therefore, the heat dissipation device is assembled together, and the first flanges 2211a and the second flanges 2213a are totally sandwiched between the main bodies 2210 and the fan 10.

During operation of the heat dissipation device, the heat-absorbing block 40 absorbs heat from the heat-generating component, then the heat is spread on the fins 221 via the heat-transferring plate 21 and the heat pipes 30, and finally the heat is dissipated to ambient air via the fins 221. The blades 13 of the fan 10 rotate in a counter clockwise direction and produce an airflow towards the fin assembly 22 in a counterclockwise spiral pattern. Since the first flanges 2211a and the second flanges 2213a are oriented towards the windward side of the airflow produced by the fan 10, the airflow produced by the fan 10 can be easily guided into the channels 222 between the fins 221. Thus, the efficiency of the forced convention between the fins 221 and the airflow produced by the fan 10 is increased.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a fan having an air inlet and an air outlet mating with the air inlet; and
a fin assembly with the fan mounted thereto, the fin assembly comprising a plurality of fins arranged one by one and a plurality of channels formed between adjacent fins, each fin comprising a main body, a first flange and a second flange;
wherein the first flange and the second flange are slantwise extended from an edge portion of the main body towards the air outlet of the fan; and
wherein the first flange and the second flange are inclined with respect to the main body, and an airflow produced by the fan is guided into the channels of the fins by the first flange and the second flange of the each fin.

2. The heat dissipation device as described in claim 1, wherein the first flange and the second flange of the each fin are located at opposite sides of the main body of the each fin.

3. The heat dissipation device as described in claim 2, wherein the first flange and the main body together define an obtuse angle.

4. The heat dissipation device as described in claim 3, wherein the obtuse angle defined by the first flange and the main body is 120 degrees.

5. The heat dissipation device as described in claim 3, wherein the second flange and the main body together define an obtuse angle.

6. The heat dissipation device as described in claim 5, wherein the obtuse angle defined by the second flange and the main body is 120 degrees.

7. The heat dissipation device as described in claim 1, wherein the each fin is connected to one adjacent fin via two engaging members formed at opposite sides of the each fin, wherein a top side of one of the engaging members neighbores a bottom side of the first flange, and a top side of the other one of the engaging members neighbores a bottom side of the second flange.

8. The heat dissipation device as described in claim 7, wherein the engaging members of the fins together define two strip-like plates on opposite lateral sides of the fin assembly.

9. The heat dissipation device as described in claim 8, wherein the strip-like plates together define a fan duct structure beneath and neighboring the first flanges and the second flanges of the fins.

10. The heat dissipation device as described in claim 1, wherein the each fin is divided into three portions including a first fin portion, a second fin portion and a third fin portion, the first fin portion and the second fin portion are located at opposite sides of the second fin portion, wherein the first flange is formed at the first fin portion and the second flange is formed at the second fin portion.

11. The heat dissipation device as described in claim 1, wherein the first flange and the second flange of the each fin are totally sandwiched between the main body of the each fin and the fan.

12. A heat dissipation device comprising:
a fin assembly comprising a plurality of fins arranged one by one and a plurality of channels formed between adjacent fins, at least some of the fins each comprising a main body and a flange extending from an edge portion of the main body;
wherein the flange and the main body together define an obtuse angle.

13. The heat dissipation device as described in claim 12, further comprising a fan mounted on the fin assembly, and the flange is oriented to point the fan.

14. The heat dissipation device as described in claim 13, wherein the flanges are oriented towards a windward side of an airflow produced by the fan.

15. The heat dissipation device as described in claim 12, wherein the obtuse angle defined by the flange and the main body is 120 degrees.

16. The heat dissipation device as described in claim 12, wherein two strip-like plates are formed on opposite lateral sides of the fin assembly, the strip-like plates together define a fan duct structure beneath and neighboring the flanges of the at least some of the fins.

17. The heat dissipation device as described in claim 12, wherein the at least some of the fins each further comprises another flange extending from the edge portion of the main body, and the another flange and the main body together define an obtuse angle.

18. The heat dissipation device as described in claim 17, wherein the flange and the another flange of each fin of the at least some of the fins are located at opposite sides of the each fin of the at least some of the fins.

19. A heat dissipation device comprising:
a plurality of fins stacked together, each fin including a first fin portion and a second fin portion, a first flange extending inclinedly outwardly from the first fin portion along an edge of the each fin, a second flange extending inclinedly outwardly from the second fin portion along the edge of each fin, the first flange and the second flange pointing towards opposite directions; and
a fan secured to the first flange and the second flange and generating an airflow guided by the first flange and the second flange towards the fins.

20. The heat dissipation device as described in claim 19, wherein the each fin has at least a groove defined therein adapted for receiving a clip mounting the heat sink to a heat-generating component, the groove dividing the each fin into the first fin portion and the second fin portion.
